(19) United States
(12) Patent Application Publication
(10) Pub. No.: US 2009/0127579 A1
(43) Pub. Date: May 21, 2009

(54) Optoelectronic device

(76) Inventor: Qinghuan Sun, Zhongshan City (CN)

Correspondence Address: NORTH AMERICA INTELLECTUAL PROPERTY CORPORATION, P.O. BOX 506, MERRIFIELD, VA, 22116, US

(21) Appl. No.: 12/099,150

(22) Filed: Apr. 8, 2008

(30) Foreign Application Priority Data
Nov. 15, 2007 (CN) 200720059783.6

(51) Int. Cl. H01L 33/00; H01L 31/0203

(52) U.S. Cl. 257/99; 257/433; 257/E31.11; 257/E33.058

(57) ABSTRACT

An optoelectronic device includes a base, a first and a second stands mounted on the base, a chip mounted on the first stand, a copper wire for bonding the chip to the second stand, and a molding compound mounted on the base. The molding compound encapsulates the first and the second stands, the chip, and the copper wire. The molding compound is made of epoxy resin.

### BACKGROUND OF THE INVENTION

1. Field of the Invention

The present invention relates to an optoelectronic device, and more particularly, to an optoelectronic device utilizing copper wire for bonding.

2. Description of the Prior Art

Since Light Emitting Diode (LED) has characteristic of long lifespan, small size, low heat, low power consumption, fast response speed, no radiation, single-colored light, it is widely applied to indication lights, billboards, traffic lights, car lamps, display panels, communication devices, consumer electronics, and so on. However, the conventional LED has complicated structure, and the chip of the conventional LED is bonded to the stand on the base through the gold wire. Because the gold wire is very expensive, the cost of manufacture for the LED cannot be reduced. Furthermore, when the conventional LED operates, the heat generated tends to gather at some area, which shortens the lifespan of the conventional LED.

### SUMMARY OF THE INVENTION

The present invention provides an optoelectronic device. The optoelectronic device comprise a base; a first stand mounted on the base; a second stand mounted on the base; a chip mounted on the first stand; a copper wire for bonding the chip to the second stand; and a molding compound mounted on the base for encapsulating the first and the second stands, the chip, and the copper wire; wherein the molding compound is made of epoxy resin.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an optoelectronic device of the present invention.

### DETAILED DESCRIPTION

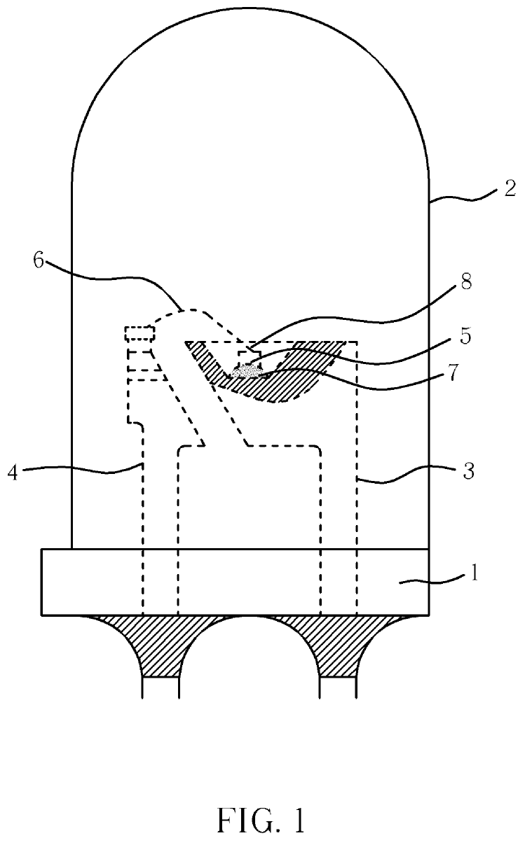

Please refer to FIG. 1. FIG. 1 is a diagram illustrating an optoelectronic device of the present invention. The optoelectronic device of the present invention comprises a base 1, an molding compound 2, two stands 3 and 4, a chip 5, a copper wire 6, a die attach 7, and a cave 8. The molding compound 2 is mounted on the base 1. The molding compound 2 can be made of epoxy resin. The molding compound 2 encapsulates the stands 3 and 4, the chip 5, and the copper wire 6. The stands 3 and 4 are mounted on the base 1. The chip 5 is mounted on the stand 3. The chip 5 is boned to the stand 4 through the copper wire 6. That is, the bonding material between the chip and the stand of the present invention is made of copper wire instead of gold wire. The copper wire utilized in the optoelectronic device of the present invention has such good conductivity and such good flexibility that the optoelectronic device of the present invention functions as well as the conventional optoelectronic device utilizing the gold wire.

As shown in FIG. 1, the chip 5 can be any optoelectronic component for emitting or absorbing light of any wavelength. The chip 5 can comprises one die, or plurality of dies. The cave 8 is disposed on the stand 3 for convenience of the chip installation. The chip 5 is fixed in the cave 8 of the stand 3 through the die attach 7.

To sum up, since the copper wire is much cheaper than the gold wire and, the optoelectronic device of the present invention can greatly reduce the cost of manufacture. Furthermore, the structure of the optoelectronic device of the present invention avoids heat generated from the operation of the optoelectronic device of the present invention gathering, which prolongs the lifespan of the optoelectronic device of the present invention.

Those skilled in the art will readily observe that numerous modifications and alterations of the device and method may be made while retaining the teachings of the invention.

What is claimed is:

1. An optoelectronic device comprising:
a base;
a first stand mounted on the base;
a second stand mounted on the base;
a chip mounted on the first stand;
a copper wire for bonding the chip to the second stand; and
a molding compound mounted on the base for encapsulating the first and the second stands, the chip, and the copper wire;
wherein the molding compound is made of epoxy resin.

2. The optoelectronic device of claim 1, wherein the chip is an optoelectronic component for emitting or absorbing light of any wavelength, and the chip comprises one die or a plurality of dies.

3. The optoelectronic device of claim 1, wherein the chip is fixed on the first stand through a die attach.

4. The optoelectronic device of claim 2, wherein the chip is fixed on the first stand through a die attach.

5. The optoelectronic device of claim 3, further comprising a cave disposed on the first stand;
wherein the chip is fixed in the cave of the first stand through a die attach.

6. The optoelectronic device of claim 4, further comprising a cave disposed on the first stand;
wherein the chip is fixed in the cave of the first stand through a die attach.
